(19) United States
(12) Patent Application Publication
(10) Pub. No.: US 2010/0097431 A1
(43) Pub. Date: Apr. 22, 2010

(54) PIEZOELECTRIC ELEMENT, LIQUID EJECTING HEAD, AND LIQUID EJECTING APPARATUS

(75) Inventor: Atsushi Takakuwa, Suwa-shi (JP)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: SEIKO EPSON CORPROATION, Shinjuku-ku (JP)

(21) Appl. No.: 12/580,416

(22) Filed: Oct. 16, 2009

(30) Foreign Application Priority Data
Oct. 17, 2008 (JP) 2008-268372
Jun. 29, 2009 (JP) 2009-153195

(51) Int. Cl. B41J 2/045; H01L 41/053

(52) U.S. Cl. 347/68; 310/340

(57) ABSTRACT

A piezoelectric element includes a substrate, a lower electrode formed above the substrate, a piezoelectric layer formed above the lower electrode, an upper electrode formed above the piezoelectric layer, a protection layer formed on the lateral sides of the piezoelectric layer, and a self-organized monomolecular film formed on the side of each of the protection layer not facing the piezoelectric layer.

The entire disclosure of Japanese patent Application Nos. 2008-268372 filed Oct. 17, 2008 and 2009-153195 filed Jun. 29, 2009 is expressly incorporated by reference herein.

### BACKGROUND

1. Technical Field

The present invention relates to a piezoelectric element, a liquid ejecting head, and a liquid ejecting apparatus.

2. Related Art

Lead zirconate titanate (hereinafter, sometimes simply referred to as “PZT”) and other materials for piezoelectric layers of piezoelectric elements may undergo dielectric breakdown on absorption of moisture. This problem has some disclosed solutions, for example, moisture barriers (protection films) for piezoelectric layers; in particular, aluminum oxide (Al₂O₃) has favorable performance in blocking moisture. For example, Japanese Unexamined Patent Application Publication No. 2005-178293 discloses a piezoelectric element that has a piezoelectric layer coated with an aluminum oxide layer.

However, aluminum oxide has a greater Young's modulus than silicon oxide and organic matter, which unfortunately prevents piezoelectric elements used therewith from being deformed. Furthermore, the use of piezoelectric elements that have a piezoelectric layer coated with an aluminum oxide layer faces a trade-off between the reduced thickness of the aluminum oxide layer for improved displacements and the deteriorated performance of the aluminum oxide layer in blocking moisture.

### SUMMARY

An advantage of some aspects of the invention is that piezoelectric elements obtained therewith make sufficiently great displacements and have robust piezoelectric layers.

A piezoelectric element according to the present invention has:

a substrate;

a lower electrode formed above the substrate;

a piezoelectric layer formed above the lower electrode;

an upper electrode formed above the piezoelectric layer;

a protection layer formed on the lateral sides of the piezoelectric layer; and

a self-organized monomolecular film formed on the side of each of the protection layer not facing the piezoelectric layer.

This piezoelectric element makes sufficiently great displacements and has a robust piezoelectric layer.

Note that the expression that Member B formed “above” Member A often used herein includes the case in which Member B is formed directly on Member A and the other case in which some other member(s) lies between Members A and B.

In the piezoelectric element according to the present invention, the protection layer may be made of at least one selected from the group consisting of silicon oxide, silicon nitride, silicon oxide-nitride, and aluminum oxide.

In the piezoelectric element according to the present invention, the protection layers may be made of at least one selected from the group consisting of a parylene resin, a polyimide resin, a polyamide resin, an epoxy resin, and an organic/inorganic hybrid material.

In the piezoelectric element according to the present invention, the protection layer may be made of a parylene resin.

In the piezoelectric element according to the present invention, the protection layer may be made of an organic/inorganic hybrid material.

A piezoelectric element according to the present invention has:

a substrate;

a lower electrode formed above the substrate;

a piezoelectric layer formed above the lower electrode; and

an upper electrode formed above the piezoelectric layer; wherein

the piezoelectric layer has at least one selected from the group consisting of self-organized monomolecular film, parylene resin layer, and organic/inorganic hybrid layer formed on the lateral sides thereof.

This piezoelectric element makes sufficiently great displacements and has a piezoelectric layer resistant to moisture.

A liquid ejecting head according to the present invention has any of the piezoelectric elements described above.

A liquid ejecting apparatus according to the present invention has the liquid ejecting head described above.

### BRIEF DESCRIPTION OF THE DRAWINGS

The invention will be described with reference to the accompanying drawings, wherein like numbers reference like members.

FIG. 1 is a cross-sectional diagram of a piezoelectric element according to the first embodiment of the present invention.

FIG. 2 is a plan view of the piezoelectric element according to the first embodiment of the present invention.

FIG. 3 is a cross-sectional diagram illustrating a step of a manufacturing process of the piezoelectric element according to the first embodiment of the present invention.

FIG. 4 is a cross-sectional diagram illustrating a step of the manufacturing process of the piezoelectric element according to the first embodiment of the present invention.

FIG. 5 is a cross-sectional diagram illustrating a step of the manufacturing process of the piezoelectric element according to the first embodiment of the present invention.

FIG. 6 is a cross-sectional diagram illustrating a step of the manufacturing process of the piezoelectric element according to the first embodiment of the present invention.

FIG. 7 is a cross-sectional diagram illustrating a step of the manufacturing process of the piezoelectric element according to the first embodiment of the present invention.

FIG. 8 is a cross-sectional diagram illustrating a step of the manufacturing process of the piezoelectric element according to the first embodiment of the present invention.

FIG. 9 is a cross-sectional diagram of a piezoelectric element according to the second embodiment of the present invention.

FIG. 10 is a cross-sectional diagram of a piezoelectric element according to the third embodiment of the present invention.

FIG. 11 is a cross-sectional diagram of a liquid ejecting head in its embodiment according to the present invention.

FIG. 12 is a brief perspective view of an ink jet recording apparatus in its embodiment according to the present invention.

FIG. 13 is a graph showing the withstand voltage achieved by some examples of the present invention.

FIG. 14 is a graph showing displacements achieved by some examples of the present invention.

### DESCRIPTION OF EXEMPLARY EMBODIMENTS

The following describes preferred embodiments of the present invention with reference to drawings. Note that each of the embodiments is just an example of the present invention.

### 1. First Embodiment

### 1.1. Piezoelectric Element

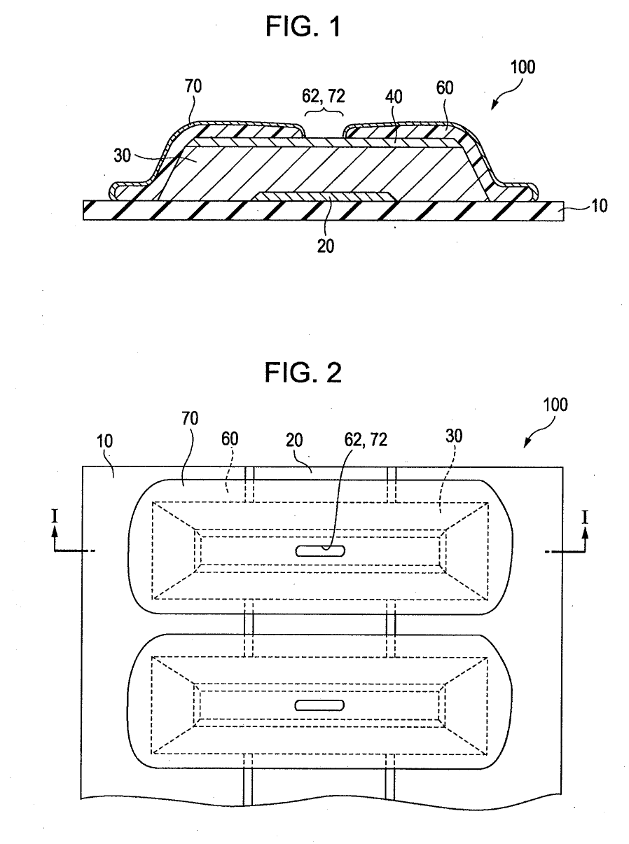

FIGS. 1 and 2 are a cross-sectional diagram and a plan view, respectively, of a piezoelectric element 100 according to the first embodiment of the present invention. The piezoelectric element 100 has a substrate 10, a lower electrode 20, a piezoelectric layer 30, an upper electrode 40, protection layers 60, and self-organized monomolecular films 70.

The substrate 10 gives mechanical outputs when the piezoelectric element 100 operates. Configured to have a diaphragm or the like, the substrate 10 can be a moving part of a liquid ejecting head or a part of walls of a pressure generator or the like. The substrate 10 has a thickness appropriately chosen on the basis of the modulus of elasticity of its material and other factors. When the substrate 10 is a diaphragm used in a liquid ejecting head, its thickness can be in the range of 200 to 2000 nm. A thickness of the substrate 10 falling below 200 nm would cause difficulties in giving mechanical outputs, such as vibrations; however, the substrate 10 cannot undergo vibrations or any other movement when its thickness exceeds 2000 nm. The substrate 10 bends or vibrates on movement of the piezoelectric layer 30. Preferably, the material of the substrate 10 contains a rigid and mechanically strong substance, for example, an inorganic oxide, such as zirconium oxide, silicon nitride, and silicon oxide, and an alloy, such as stainless steel. In particular, zirconium oxide has excellent chemical stability and rigidity and thus can be more suitably used than others. In addition, the substrate 10 may be a laminate constituted by two or more kinds of the substances listed above.

As shown in FIG. 2, the piezoelectric element 100 may have a plurality of structures each having a lower electrode 20, a piezoelectric layer 30, and an upper electrode 40.

The lower electrode 20 is formed above, or directly on, the substrate 10. When the upper surface of the substrate 10 is conductive, there may be an insulator between the lower electrode 20 and the substrate 10. The lower electrode 20, in pairs with the upper electrode 40, provides an electrode that puts the piezoelectric layer 30 therebetween. An example configuration of the lower electrode 20 is one shown in FIG. 2, in which the lower electrode 20 is used also by adjacent capacitors. The lower electrode 20 is electrically connected to an external circuit not shown in the drawing and may have any thickness that enables the lower electrode 20 to transmit displacements of the piezoelectric layer 30 to the substrate 10, for example, a thickness in the range of 100 to 300 nm. The material of the lower electrode 20 may be every conductive substance including metals, such as nickel, iridium, and platinum, conductive metal oxides, such as iridium oxide, and complex oxides, such as strontium/ruthenium oxide and lanthanum/nickel oxide. In addition, the lower electrode 20 may be a layer of any of the listed materials or a laminate of two or more of the materials.

The piezoelectric layer 30 is formed above the lower electrode 20; in FIGS. 1 and 2, it covers also the substrate 10. The thickness of the piezoelectric layer 30 may be in the range of 500 to 1500 nm, and a failure to meet this condition would possibly end up with too small deformations to deform the substrate 10. When energized by the lower electrode 20 and the upper electrode 40, the piezoelectric layer 30 stretches and contracts, by which the substrate 10 bends or vibrates. The material of the piezoelectric layer 30 may be piezoelectric matter, and preferred applicable examples include perovskite oxides represented by a general formula ABO₃ (e.g., A is Pb and B is Zr or Ti). Specific examples are, for example, lead zirconate titanate (or PZT; Pb(Zr, Ti)O₃), lead zirconate titanate niobate (or PZTN; Pb(Zr, Ti, Nb)O₃), barium titanate (BaTiO₃), and sodium potassium niobate ((K, Na)NbO₃). In particular, PZT and PZTN have excellent piezoelectric properties and thus serve as suitable materials for the piezoelectric layer 30.

The upper electrode 40 is formed above the piezoelectric layer 30 and may have any thickness that has no adverse effects on movement of the piezoelectric element 100, for example, a thickness in the range of 50 to 200 nm. A thickness of the upper electrode 40 falling below 50 nm would possibly cause increases in electric resistance; however, a thickness of the upper electrode 40 exceeding 200 nm would possibly obstruct deformations of the piezoelectric element 100. In pairs with the lower electrode 20, the upper electrode 40 provides an electrode of the piezoelectric element 100. The material of the upper electrode 40 may be every conductive substance that functions as described above including metals, such as nickel, iridium, gold, and platinum, conductive metal oxides, such as iridium oxide, and complex oxides, such as strontium/ruthenium oxide and lanthanum/nickel oxide. In addition, the upper electrode 40 may be a layer of any of the listed materials or a laminate of two or more of the materials.

The protection layers 60 are formed on the lateral sides of the piezoelectric layer 30; in FIG. 1, they reach also the upper electrode 40 and the substrate 10 with some portions thereof positioned above the lower electrode 20. However, the protection layers 60 can work as intended as long as they formed so as to cover at least the lateral sides of the piezoelectric layer 30. The protection layers 60 keep the piezoelectric layer 30 intact by blocking moisture, hydrogen molecules, reducing gases, and other kinds of foreign matter entering or diffusing into the piezoelectric layer 30. In other words, the protection layers 60 can act as barriers against moisture and other kinds of foreign matter, with which the piezoelectric layer 30 is protected against foreign matter, and current leakage from the lateral sides of the piezoelectric layer 30 can be reduced. The thickness of each protection layer 60 depends on the material of the protection layer 60; however, it preferably falls within the range of 1 to 2000 nm. A thickness of each protection layer 60 falling below 1 nm would possibly result in insufficient barrier performance; however, a thickness of each protection layer 60 exceeding 2000 nm would possibly cause restrictions on movements of the piezoelectric element 100. The barrier performance and rigidity of each protection layer 60 depends on the thickness of the protection layer 60; the thicker the protection layer 60 is, the more improved both properties are.

The material of the protection layer 60 preferably has a maximum possible performance in blocking foreign matter and a minimum possible Young's modulus. Examples of applicable substances are inorganic compounds such as silicon oxide, silicon nitride, silicon oxide-nitride, and aluminum oxide; one or more organic compounds selected from the following resins and denatured forms of the organic compounds: parylene, polyimide, polyamide, epoxy, phenol, melamine, urea, benzoguanamine, polyurethane, unsaturated polyester, allyl, alkyd, epoxy acrylate, and silicone resins; and organic/inorganic hybrid materials. The protection layers 60 may be made of at least one of the materials listed above.

Among others, inorganic compounds have a better performance in blocking foreign matter but have a greater Young's modulus. When each protection layer 60 is made of such inorganic compounds, therefore, its thickness is preferably in the range of 1 to 1000 nm. In addition, silicon oxide is a particularly preferred inorganic compound that can be used as the material of the protection layers 60. Silicon oxide, whose contact angle to water is approximately 20°, is not very hydrophobic; however, the presence of the self-organized monomolecular films 70 improves hydrophobicity as described later. Furthermore, the contact angle to water of silicon nitride and aluminum oxide is 80° and 65°, respectively, and their hydrophobicity can also be improved by the presence of the self-organized monomolecular films 70 as described later.

On the other hand, organic compounds have a smaller Young's modulus (≦1×10¹⁰ Pa) but have worse performance in blocking foreign matter than others. When each protection layer 60 is made of such organic compounds, therefore, its thickness may be in the range of 100 to 2000 nm. Incidentally, the material of each protection layer 60 can desirably block gaseous foreign matter as described above, but some organic compounds cannot or hardly do so. However, organic compounds generally have a small Young's modulus and thus allow protection layers 60 made of them to have a thickness as large as approximately 2000 nm. Therefore, various organic compounds can be used as the material of the protection layers 60.

In particular, parylene resins are highly suitable as the material of the protection layers 60 because of their sufficiently small Young's modulus (≦1×10¹⁰ Pa) and excellent performance in blocking foreign matter. Specific examples of applicable parylene resins include poly-monochloro-paraxylylene and poly-paraxylylene, which are also commercially available from Nihon Parylene LLC. under the trade names of Parylene C and Parylene N.

The organic/inorganic hybrid materials mentioned above have better balanced performance in blocking foreign matter and Young's modulus than others. When each protection layer 60 is made of such hybrid materials, therefore, its thickness may be in the range of 1 to 2000 nm.

In addition, organic/inorganic hybrid materials are obtained by combining organic components and inorganic components on the nanometer level and thus benefit from synergistic effects of organic and inorganic materials. Specific examples of applicable hybrid materials include polysiloxane materials, which can be processed to have photosensitivity and thus can be easily patterned by exposure through a mask.

The self-organized monomolecular films 70 are formed on the side of each protection layer 60 not facing the piezoelectric layer 30. The self-organized monomolecular films 70 have the effect described below and can work as intended as long as they are formed so as to cover at least the lateral sides of the piezoelectric layer 30; in FIGS. 1 and 2, they reach also the upper electrode 40 and the substrate 10 with some portions thereof positioned above the lower electrode 20. The self-organized monomolecular films 70 keep the piezoelectric layer 30 intact by blocking external moisture entering or diffusing into the piezoelectric layer 30, thereby reducing current leakage from the lateral sides of the piezoelectric layer 30, and their performance in blocking moisture is better than that of the protection layers 60. The thickness of each self-organized monomolecular film 70 is preferably in the range of 1 to 10 nm. A thickness of each self-organized monomolecular film 70 falling below 1 nm would possibly result in insufficient barrier performance; however, self-organized monomolecular films 70 each having a thickness exceeding 10 nm would possibly face difficulties in organizing their structures.

Each self-organized monomolecular film 70 is composed of at least one monomolecular layer and thus may be a built-up film obtained by laminating two or more monomolecular layers. In general, the term “self-organized” means that any matter spontaneously forms an ordered structure; in this embodiment, it means that the monomolecular films are formed without special external control. In each self-organized monomolecular film 70 used in this embodiment, highly hydrophobic atoms or atomic groups are arranged on one side of each monomolecular layer. In other words, at least one side of each self-organized monomolecular film 70 has densely arranged highly hydrophobic atoms or atomic groups. This side hardly adsorbs water molecules and thus provides the self-organized monomolecular film 70 with resistance to penetration by water molecules, namely, an ability to block moisture.

Each self-organized monomolecular film 70 used in this embodiment has highly hydrophobic atoms or atomic groups arranged at least on its side opposite to the piezoelectric layer 30, and these hydrophobic atoms or atomic groups block external moisture entering or diffusing into the piezoelectric layer 30, thereby further reducing current leakage from the lateral sides of the piezoelectric layer 30.

The material of each self-organized monomolecular film 70 should be one that can organize a monomolecular layer by itself and has hydrophobic groups, for example, fluoroalkylsilane (hereinafter, sometimes simply referred to as “FAS”), alkylsilane, and hexamethyldisilazane. Each of these materials can organize a monomolecular layer by itself while concentrating fluorine-containing groups or alkyl groups on a side of the monomolecular layer, thereby making this side hydrophobic. In particular, FAS is highly suitable because fluorine-containing groups contained therein offer better hydrophobicity when concentrated. The surface hydrophobicity of a self-organized monomolecular film 70 can be determined on the basis of contact angle to water. In this embodiment, the contact angle to water of the self-organized monomolecular films 70 is preferably equal to or greater than 50°.

Such self-organized monomolecular films 70 can be formed by thermal CVD (chemical vapor deposition), ink jet printing, spin coating, or the like. Any of these methods can form self-organized monomolecular films each having the internal molecular structure described above with no special control needed. When formed by thermal CVD or spin coating, the self-organized monomolecular film 70 covers the entire surface of the piezoelectric element 100 and then is subjected to necessary treatments such as patterning. In FIGS. 1 and 2, the self-organized monomolecular films 70 are formed so as to cover the protection layers 60 only. Ink jet printing is a preferred method because it saves materials by forming self-organized monomolecular films 70 selectively on the side of each protection layers 60 not facing the piezoelectric layer 30.

The following describes the features of the piezoelectric element 100 according to this embodiment. The piezoelectric element 100 has a piezoelectric layer 30 each side of which is covered with a laminate of a protection layer 60 and a self-organized monomolecular film 70, and this structure blocks moisture and other kinds of foreign matter entering or diffusing into the piezoelectric layer 30. As a result, the piezoelectric layer 30 is robust, and current leakage therefrom is reduced. Note that the piezoelectric element 100 has self-organized monomolecular films 70 besides protection layers 60. The self-organized monomolecular films 70, made of organic materials, scarcely restrict deformations of the piezoelectric layer 30 and those of the substrate 10. Furthermore, the self-organized monomolecular films 70 have an ability to block moisture, by which they share the responsibility for blocking external moisture with the protection layers 60. Thus, the protection layers 60 can be thinner than in the case without the self-organized monomolecular films 70, and this reduces restrictions due to the presence of the protection layers 60 on deformations and movements of the piezoelectric element 100. Therefore, the piezoelectric element 100 makes greater displacements, and it can also withstand higher voltages because the piezoelectric layer 30 contained therein is robust and leaks less current.

### 1.2. Method for Manufacturing the Piezoelectric Element

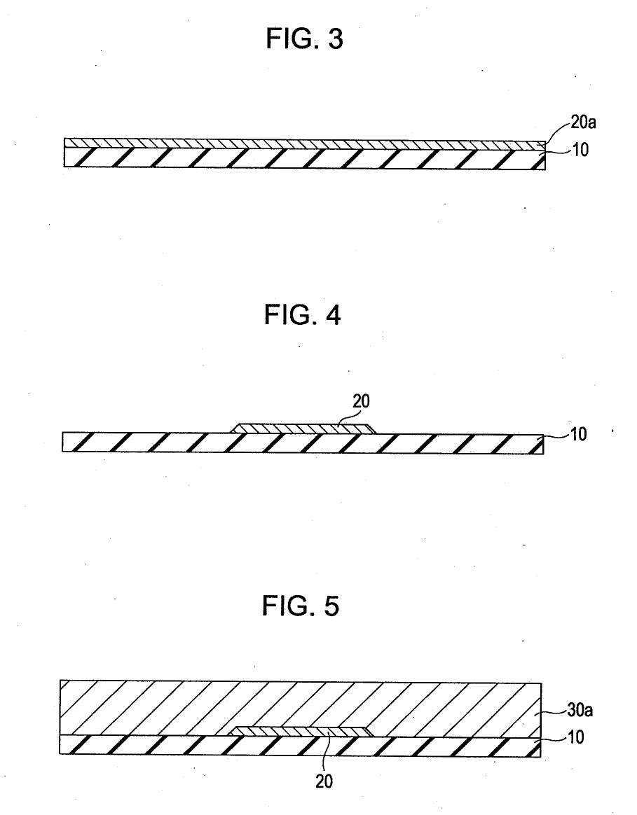

FIGS. 3 to 7 are cross-sectional diagrams taken along the I-I line in FIG. 2, each showing a step of a manufacturing process of the piezoelectric element 100 according to this embodiment.

This method includes a step of forming a lower electrode layer 20a, a step of forming a piezoelectric layer 30a and an upper electrode layer 40a in this order, a step of patterning the piezoelectric layer 30a and the upper electrode layer 40a, a step of forming protection layers 60, and a step of forming self-organized monomolecular films 70.

First, a substrate 10 is prepared and a lower electrode layer 20a is formed on the substrate 10 as shown in FIG. 3 by sputtering, vacuum deposition, CVD, or the like.

The next step is a first patterning step, in which the lower electrode layer 20a is etched by photolithography or the like to form a lower electrode 20 as described in FIG. 4.

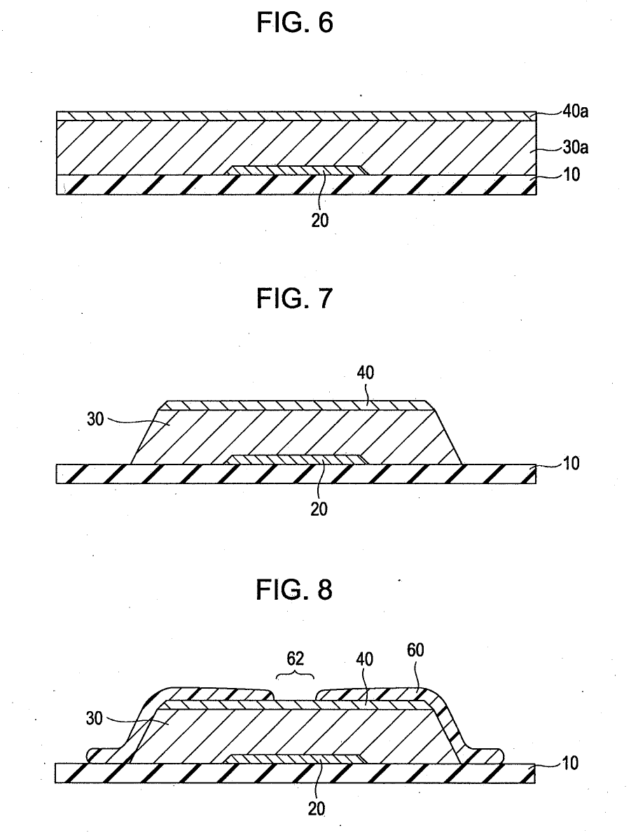

Then, a piezoelectric layer 30a and an upper electrode layer 40a are formed in this order. More specifically, the piezoelectric layer 30a is formed on the substrate 10 and the lower electrode 20 as shown in FIG. 5 by a sol-gel method, CVD, or the like. When a sol-gel method is used, a cycle consisting of application of a solution containing raw materials, preheating, and annealing for crystallization may be repeated until the film thickness reaches a desired value. Then, the upper electrode layer 40a is formed on the piezoelectric layer 30a as shown in FIG. 6 by sputtering, vacuum deposition, CVD, or the like. Note that annealing for crystallization of the piezoelectric layer 30a may come after the formation of the upper electrode layer 40a.

Then, as shown in FIG. 7, at least the piezoelectric layer 30a and the upper electrode layer 40a are patterned to form a capacitor consisting of the lower electrode 20 and remaining portions of the piezoelectric layer 30a and the upper electrode layer 40a, namely, a piezoelectric layer 30 and an upper electrode 40. This step can be completed by repeated photolithographic operations using a mask or the like, dry etching according to a known procedure, or some other possible method.

Then, protection layers 60 shown in FIG. 8 are formed. When silicon oxide is used as the material of the protection layers 60, a possible method is CVD of trimethoxysilane. This method prevents hydrogen generation, thereby preventing the piezoelectric layer 30 from being chemically reduced during this step, and makes it possible to produce quality protection layers 60 even at low temperatures. More specifically, this step may be completed as follows: a protection layer 60 is formed and then patterned to have an opening 62 for assuring electrical contact to the upper electrode 40 or other purposes; then, the portions of the protection layers 60 remaining on the substrate 10 are removed by patterning, if necessary.

Then, self-organized monomolecular films 70 are formed, as shown in FIGS. 1 and 2, on the side of each protection layer 60 not facing the piezoelectric layer 30. When FAS is used as the material of the self-organized monomolecular films 70, a possible method is thermal CVD of FAS according to a known procedure. More specifically, this step may be completed as follows: a self-organized monomolecular film 70 is formed on the entire surface of the piezoelectric element 100, which includes the side of each protection layer 60 not facing the piezoelectric layer 30; then, the self-organized monomolecular film 70 is patterned to have an opening 72 for assuring electrical contact to the upper electrode 40 or other purposes; then, the remaining portions of the self-organized monomolecular films 70 are removed by patterning, if necessary. Note that this step for forming the self-organized monomolecular films 70 may come after the upper electrode 40 is given necessary electrical connection.

Preferably, the protection layers 60 and the self-organized monomolecular films 70 are formed after the base structure is heated at a temperature equal to or higher than 100° C. This heating treatment removes water molecules and other adsorbent substances existing in the base structure, thereby making the piezoelectric layer 30 more robust.

Note that the protection layers 60 and the self-organized monomolecular films 70 may be formed by spraying droplets of their precursor materials onto target sites. Droplet spraying is a method that is suitable for applying a liquid onto a semiconductor substrate or the like, in which the amount of the liquid and the locations of the target sites can be programmed so that a coating having a fine pattern can be produced. This means that the precursor materials can be applied selectively to the vicinity of the capacitor as shown in FIGS. 1 and 2. When droplet spraying is used, therefore, the protection layers 60 and the self-organized monomolecular films 70 can be formed selectively on the lateral sides of the piezoelectric layer 30, and thus the steps of pattering the protection layers 60 and the self-organized monomolecular films 70 are unnecessary. An example precursor material of the protection layers 60 is a solution of a polysiloxane material in mesitylene. This solution is applied to target sites, and then the solvent is dried away, leaving the protection layers 60. Also, an example precursor material of the self-organized monomolecular films 70 is a solution of FAS in hexane. This solution is applied to target sites, and then the solvent is dried away, leaving the self-organized monomolecular films 70.

The foregoing is a method for manufacturing the piezoelectric element 100 according to this embodiment. Note that this method may include a step of forming other members, a step of surface treatment, or any other necessary step.

### 2. Second Embodiment

### 2.1. Piezoelectric Element

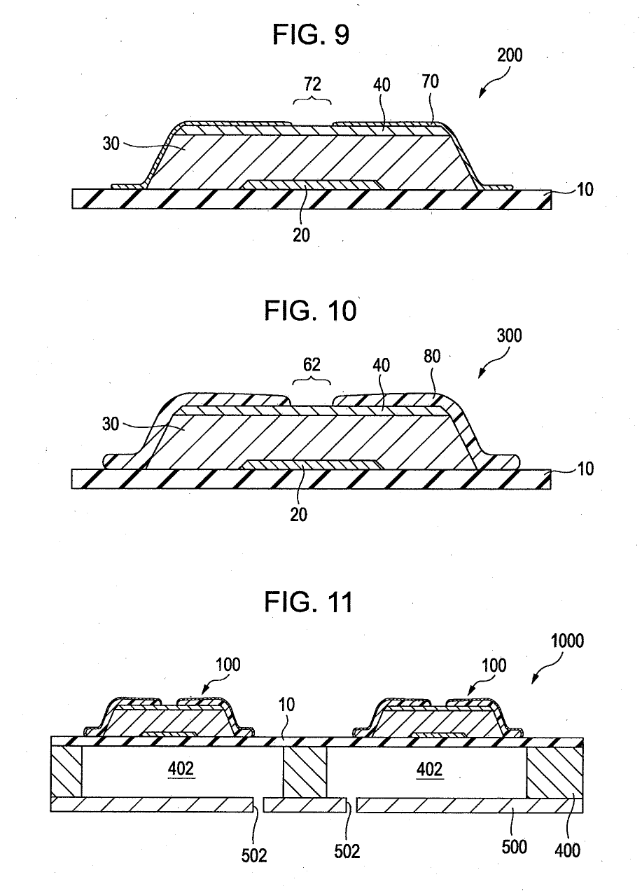

FIG. 9 is a cross-sectional diagram of a piezoelectric element 200 according to the second embodiment of the present invention. The piezoelectric element 200 has the same configuration as the piezoelectric element 100 according to the first embodiment of the present invention, except for the absence of the protection layers 60. Thus, like numbers reference like members in the piezoelectric element 100 for simplicity of description.

The piezoelectric element 200 according to this embodiment has a substrate 10, a lower electrode 20, a piezoelectric layer 30, an upper electrode 40, and self-organized monomolecular films 70.

As described in the first embodiment, the self-organized monomolecular films 70 have an excellent ability to block moisture. The piezoelectric element 200 has such self-organized monomolecular films 70 on the lateral sides of the piezoelectric layer 30 for the prevention of external moisture from entering or diffusing into the piezoelectric layer 30. As a result, the piezoelectric layer 30 is robust, and current leakage therefrom is reduced. Furthermore, the self-organized monomolecular films 70, made of organic materials, scarcely restrict deformations of the piezoelectric layer 30 and those of the substrate 10, thereby assuring virtually free displacements and movements of the piezoelectric element 200. Therefore, the piezoelectric element 200 makes greater displacements, and it can also withstand higher voltages because the piezoelectric layer 30 contained therein is robust and leaks less current.

### 2.2 Method for Manufacturing the Piezoelectric Element

The method for manufacturing the piezoelectric element 200 is the same as that for the piezoelectric element 100, except for the absence of the step of forming the protection layers 60.

### 3. Third Embodiment

### 3.1. Piezoelectric Element

FIG. 10 is a cross-sectional diagram of a piezoelectric element 300 according to the third embodiment of the present invention. The piezoelectric element 300 has the same configuration as the piezoelectric element 100 according to the first embodiment of the present invention, except for the absence of the self-organized monomolecular films 70 and the presence of parylene resin layers 80 used instead of the protection layers 60. Thus, like numbers reference like members in the piezoelectric element 100 for simplicity of description.

The piezoelectric element 300 according to this embodiment has a substrate 10, a lower electrode 20, a piezoelectric layer 30, an upper electrode 40, and parylene resin layers 80.

As described in the first embodiment, parylene resins have sufficiently small Young's modulus (≦1×10¹⁰ Pa) and excellent performance in blocking foreign matter such as moisture, hydrogen molecules, and reducing gases. Thus, the use of any parylene resin in the piezoelectric element 100 according to the first embodiment as the material of the protection layers 60 eliminates the need for the self-organized monomolecular films 70 while assuring great displacements of the piezoelectric element and maintaining the robustness of the piezoelectric layer 30.

The piezoelectric element 300 has parylene resin layers 80 on the lateral sides of the piezoelectric layer 30, and the parylene resin layers 80 have an excellent ability to block foreign matter entering or diffusing into the piezoelectric layer 30 as described above. As a result, the piezoelectric layer 30 is robust, and current leakage therefrom is reduced. Furthermore, the parylene resin layers 80, which have a small Young's modulus, scarcely restrict deformations of the piezoelectric layer 30 and those of the substrate 10, thereby assuring virtually free displacements and movements of the piezoelectric element 300. Therefore, the piezoelectric element 300 makes greater displacements, and it can also withstand higher voltages because the piezoelectric layer 30 contained therein is robust and leaks less current.

### 3.2. Method for Manufacturing the Piezoelectric Element

The method for manufacturing the piezoelectric element 300 is the same as that for the piezoelectric element 100, except that the step of forming the self-organized monomolecular films 70 is omitted and that the protection layers 60 are formed from a parylene resin.

### 3.3 Modified Embodiment

The third embodiment of the present invention can be modified in such a manner that the parylene resin layers 80 are replaced with organic/inorganic hybrid material layers.

As described in the first embodiment, organic/inorganic hybrid materials have better balanced performance in blocking impurities and Young's modulus than other materials. Thus, the use of any organic/inorganic hybrid material in the piezoelectric element 100 according to the first embodiment as the material of the protection layers 60 eliminates the need for the self-organized monomolecular films 70 while assuring great displacements of the piezoelectric element and maintaining the robustness of the piezoelectric layer 30. Configured as above, this modified embodiment also ensures that the piezoelectric layer 30 is robust and that current leakage from the piezoelectric layer 30 is reduced.

The method for manufacturing the piezoelectric element according to this modified embodiment is the same as that for the piezoelectric element 100, except that the step of forming the self-organized monomolecular films 70 is omitted and that the protection layers 60 are formed from an inorganic/organic hybrid material.

Another possible modified embodiment is a piezoelectric element that has a laminate of protection layers 60, for example, a piezoelectric element that has a laminate of protection layers 60 constituted by two or more selected from inorganic/organic hybrid material layers, parylene resin layers, and self-organized monomolecular films. The layers constituting the laminate may be overlapped in any order. When self-organized monomolecular films are chosen, at least one of these highly hydrophobic films is preferably formed on the side of each protection layer 60 not facing the piezoelectric layer 30.

### 4. Liquid Ejecting Head

FIG. 11 is a cross-sectional diagram showing major components of a liquid ejecting head 1000. The liquid ejecting head 1000 has at least piezoelectric elements each of which is any kind of those described above, a pressure chamber substrate 400, and a nozzle plate 500. In the following embodiment, each of the piezoelectric elements formed on the liquid ejecting head 1000 is the piezoelectric element 100 according to the first embodiment. The diaphragm of the liquid ejecting head 1000 corresponds to the substrate 10 of the piezoelectric element 100.

The pressure chamber substrate 400, formed beneath the piezoelectric elements 100, has pressure chambers 402. Each pressure chamber 402 is filled with a fluid to be ejected therefrom, and the fluid is supplied from an external reservoir via a fluid channel, although the reservoir and the fluid channel are not shown in the drawing. Deformations of the substrate 10 of each piezoelectric element 100 lead to changes in the volume of the corresponding pressure chamber 402, and the changes in volume generate changes in pressure, thereby allowing the fluid to be discharged through the nozzle hole 502 described later.

The nozzle plate 500 is formed beneath the pressure chamber substrate 400 and has nozzle holes 502. Located so as to be coupled with the individual pressure chambers 402, the nozzle holes 502 discharge the fluids contained in their corresponding pressure chambers 402. The pressure chamber substrate 400 may be made of any material, for example, silicon, stainless steel, nickel, titanium, and titan alloy. In addition, the use of silicon as the material of the pressure chamber substrate 400 allows the pressure chamber substrate 400 and the nozzle plate 500 to be formed from silicon substrates.

The liquid ejecting head 1000 has the piezoelectric elements 100, and thus the diaphragm covering the pressure chambers 402, namely, the substrate 10 common for the piezoelectric elements 100, can make great displacements. Therefore, the liquid ejecting head 1000 stably discharges greater amounts of fluids than known ones with the piezoelectric layer 30 of each piezoelectric element 100 kept intact and current leakage from the piezoelectric layers 30 reduced.

The liquid ejecting head according to this embodiment can be suitably used as a recording head for a printer or some other image recording apparatus, a colorant ejecting head for manufacturing of color filters for liquid crystal displays or the like, a liquid material ejecting head for manufacturing of electrodes and color filters for displays such as organic electroluminescence displays, field emission displays, surface emitting displays, and electrophoretic displays, a bioorganic material ejecting head for manufacturing of biochips, and so forth.

### 5. Liquid Ejecting Apparatus

The following describes an ink jet recording apparatus 2000 that ejects ink loaded in the liquid jet head 1000 as an embodiment of liquid ejecting apparatuses according to the present invention. In other words, liquid ejecting apparatuses according to the present invention include every apparatus that ejects a liquid material using the liquid eject head described above.

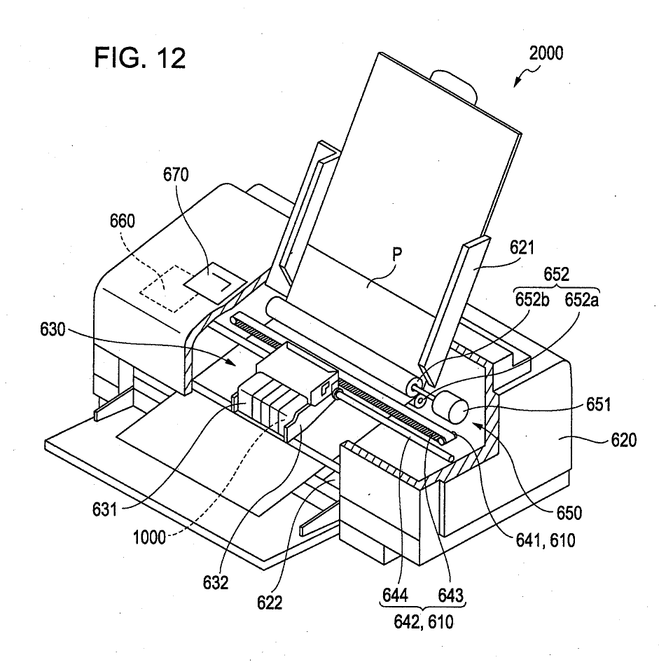

FIG. 12 is a perspective view of an ink jet recording apparatus 2000 according to the present invention. Besides the liquid ejecting head 1000 described above, the ink jet recording apparatus 2000 has a head unit 630, a drive 610, and a control unit 660 and may further have a main unit 620, a feeder 650, a tray 621 for a medium P (recording paper), an outlet 622 for the medium P, and a console 670 formed on the top of the main unit 620.

The head unit 630 has an ink jet recording head (hereinafter, sometimes simply referred to as a “head”) configured using the liquid ejecting head 1000 described earlier as well as ink cartridges 631 that individually supply inks to the head and a carriage 632 that accommodates the head and the ink cartridges 631.

The drive 610 reciprocates the head unit 630 and has a carriage motor 641 that generates force for reciprocating the head unit 630 and a reciprocator 642 that converts rotations of the carriage motor 641 into reciprocations of the head unit 630. The liquid ejecting head 1000 is attached to the head unit 630 with the direction of lamination of the driving units thereof in parallel with that of reciprocations of the head unit 630.

The reciprocator 642 has a carriage guiding shaft 644 both ends of which are held by a frame (not shown in the drawing) and a timing belt 643 extending parallel to the carriage guiding shaft 644. The carriage guiding shaft 644 supports the carriage 632 in such a manner that free reciprocations of the carriage 632 can be assured. Some portions of the carriage 632 are fixed also to the timing belt 643. When the carriage motor 641 drives the timing belt 643 to run, the head unit 630 moves in horizontal directions along the carriage guiding shaft 644. During this reciprocation movement, the head discharges inks to make a print on the medium P.

The control unit 660 controls the head unit 630, the drive 610, and the feeder 650.

The feeder 650 feeds the medium P placed on the tray 621 to the side on which the head unit 630 is located, and it has a feeder motor 651 that generates force for driving it and feeder rollers 652 that rotate as the feeder motor 651 operates. The feeder rollers 652 include a driven roller 652a provided in the lower position and a driving roller 652b provided in the upper position, and the medium P is fed through between the two rollers. The driving roller 652b is connected to the feeder motor 651. When the control unit 660 actuates the feeder 650, the medium P is fed to pass under the head unit 630.

The head unit 630, the drive 610, the control unit 660, and the feeder 650 are built in the main unit 620.

The foregoing describes an ink jet recording apparatus 2000 in the form of an ink jet printer as an embodiment of liquid ejecting apparatuses according to the present invention; however, liquid ejecting apparatuses according to the present invention also support industrial use. Examples of fluids (liquid materials) that can be used in industrial applications include various functional materials preconditioned with solvents or disperse media so as to have appropriate viscosities. Although the embodiment thereof described herein is a printer, the liquid ejecting apparatus according to this embodiment can be suitably used also as a colorant ejecting apparatus for manufacturing of color filters for liquid crystal displays or the like, a liquid material ejecting apparatus for manufacturing of electrodes and color filters for displays such as organic electroluminescence displays, field emission displays, surface emitting displays, and electrophoretic displays, a bioorganic material ejecting apparatus for manufacturing of biochips, and so forth.

### 6. Examples

The following describes the present invention in more detail with reference to examples; however, these examples never limit the present invention. Example elements were prepared as follows.

First, a substrate covered with a zirconium oxide film was further covered with a platinum film formed by sputtering, and then the platinum film was patterned into a lower electrode. Then, a PZT film and another platinum film were formed in this order and patterned into a blank piezoelectric element that had no protection layers, self-organized monomolecular films, or parylene resin layers. This procedure was repeated under the same conditions to produce several blank piezoelectric elements.

Some of the blank piezoelectric elements were individually covered with an aluminum oxide film formed by sputtering. The aluminum oxide film was patterned into an electrode, and then the lower and upper electrodes were electrically wired. The obtained elements were different in terms of the thickness of the aluminum oxide film as follows: 20, 50, 100, and 200 nm.

Some others of the blank piezoelectric elements were individually covered with a silicon oxide film formed from trimethoxysilane by CVD. The silicon oxide film was patterned into an electrode, and then the lower and the upper electrodes were electrically wired. The obtained elements were different in terms of the thickness of the silicon oxide film as follows: 20, 50, 100, and 200 nm.

Some others of the blank piezoelectric elements were individually covered with a silicon oxide film formed from trimethoxysilane by CVD. The silicon oxide film was patterned into an electrode, and then the lower and the upper electrodes were electrically wired. Subsequently, an FAS film was formed on each of the piezoelectric elements by CVD. The obtained elements were different in terms of the thickness of the silicon oxide film as follows: 20, 50, 100, and 200 nm; however, the thickness of the FAS film was in the range of 2 to 3 nm in every piezoelectric element involved.

Some others of the blank piezoelectric elements were individually covered with a Parylene C (poly-monochloro-paraxylylene) film formed by vapor deposition. The Parylene C film was patterned into an electrode, and then the lower and the upper electrodes were electrically wired. The obtained elements were different in terms of the thickness of the Parylene C film as follows: 20, 50, 100, and 200 nm.

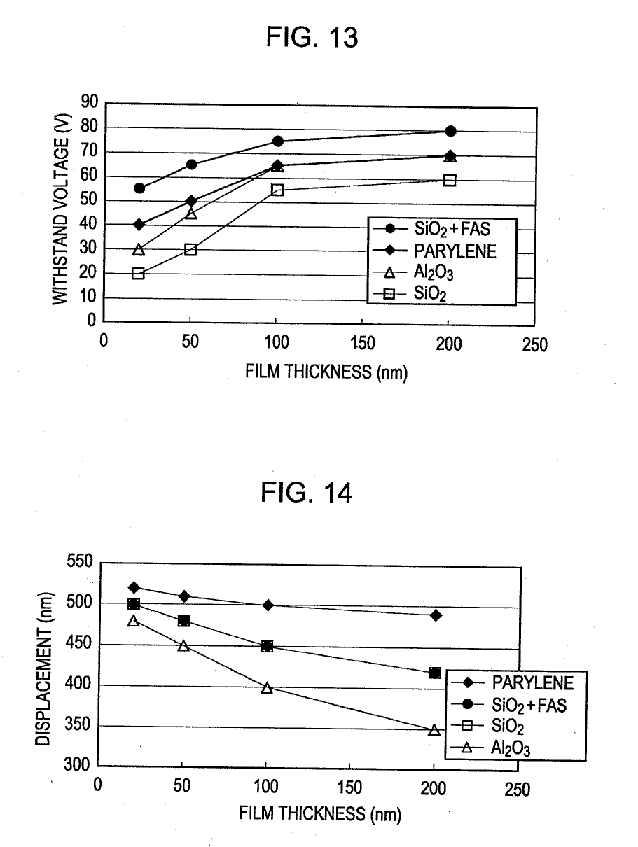

Every sample film obtained underwent measurement of withstand voltage and displacement. The voltage applied to the upper and the lower electrodes was increased until dielectric breakdown, and the breakdown voltage was recorded as the withstand voltage. Also, the displacement of the substrate (diaphragm) was recorded at the time point the voltage applied to the upper and the lower electrodes reached 30 V. The measured withstand voltage and displacement were plotted against the thickness of the covering film as shown in FIGS. 13 and 14, respectively.

FIG. 13 shows that the elements covered only with a silicon oxide film had lower withstand voltages regardless of the thickness of the film and that those covered with a silicon oxide film and an FAS film had higher withstand voltages regardless of the thickness of the films. The elements covered only with an aluminum oxide film and those covered only with a Parylene C film had moderate withstand voltages; however, those covered only with a Parylene C film were better in terms of withstand voltage in the cases where the thickness of the film was 50 nm or less.

FIG. 14 shows that the elements covered only with an aluminum oxide film made smaller displacements regardless of the thickness of the film and that those covered only with a Parylene C film made greater displacements regardless of the thickness of the film. The elements covered only with a silicon oxide film and those covered with a silicon oxide film and an FAS film made similar and moderate displacements.

FIGS. 13 and 14 reveal the following facts:

elements covered with silicon oxide and FAS are excellent in terms of withstand voltage and favorable in terms of displacement;

elements covered only with Parylene C are favorable in terms of withstand voltage and excellent in terms of displacement;

elements covered only with aluminum oxide are favorable in terms of withstand voltage but insufficient in terms of displacement; and

elements covered only with silicon oxide are insufficient in terms of withstand voltage but favorable in terms of displacement.

This means that piezoelectric elements having protection layers and self-organized monomolecular films and those having parylene resin layers can make great displacements with current leakage therefrom reduced. In addition, polysiloxane-based piezoelectric elements also had similar characteristics to those having parylene resin layers.

The present invention is never limited to the embodiments described above, and various modifications can be made; for example, configurations virtually equivalent to those described in the embodiments (e.g., ones that have the same function, utilize the same method, and bring the same result as those described in the embodiments or ones that are designed for the same object and the same advantages as those described in the embodiments), configurations that have minor members changed from those used in the configurations described in the embodiments, configurations that operate in the same manner, offer the same advantages, and achieve the same object as those described in the embodiments, and configurations obtained by adding known technologies to those described in the embodiments.

What is claimed is:

1. A piezoelectric element comprising:
a substrate;
a lower electrode formed above the substrate;
a piezoelectric layer formed above the lower electrode;
an upper electrode formed above the piezoelectric layer;
a protection layer formed on the lateral sides of the piezoelectric layer; and
self-organized monomolecular film formed on the side of each of the protection layer not facing the piezoelectric layer.

2. The piezoelectric element according to claim 1, wherein:
the protection layer is made of at least one selected from the group consisting of silicon oxide, silicon nitride, silicon oxide-nitride, and aluminum oxide.

3. The piezoelectric element according to claim 1, wherein:
the protection layer is made of at least one selected from the group consisting of a parylene resin, a polyimide resin, a polyamide resin, an epoxy resin, and an organic/inorganic hybrid material.

4. The piezoelectric element according to claim 1, wherein:
the protection layer is made of a parylene resin.

5. The piezoelectric element according to claim 1, wherein:
the protection layer is made of an organic/inorganic hybrid material.

6. A piezoelectric element comprising:
a substrate;
a lower electrode formed above the substrate;
a piezoelectric layer formed above the lower electrode; and
an upper electrode formed above the piezoelectric layer; wherein
the piezoelectric layer has at least one selected from the group consisting of self-organized monomolecular film, parylene resin layer, and organic/inorganic hybrid layer formed on the lateral sides thereof.

7. A liquid ejecting head comprising the piezoelectric layer according to claims 1.

8. A liquid ejecting apparatus comprising the liquid ejecting head according to claim 7.
